(19) United States
(12) Patent Application Publication
(10) Pub. No.: US 2015/0014693 A1
(43) Pub. Date: Jan. 15, 2015

(54) DISPLAY SUBSTRATE AND METHOD OF MANUFACTURING THE SAME

(71) Applicant: Samsung Display Co., LTD., Yongin-City (KR)

(72) Inventors: Yu-Jin LEE, Asan-si (KR); Jun-Ho SONG, Seongnam-si (KR); Hwa-Yeul OH, Seoul (KR); Su-Mi LEE, Hwaseong-si (KR); Yeon-Mun JEON, Hwaseong-si (KR); Young-Je CHO, Asan-si (KR); Tae-Hyung HWANG, Seoul (KR)

(73) Assignee: Samsung Display Co., LTD., Yongin-City (KR)

(21) Appl. No.: 14/231,040

(22) Filed: Mar. 31, 2014

(30) Foreign Application Priority Data
Jul. 15, 2013 (KR) 10-2013-0082714

(51) Int. Cl. H01L 27/12

(52) U.S. Cl. CPC H01L 27/124; H01L 27/1259
USPC 257/72; 438/158

(57) ABSTRACT

A display substrate is provided. The display substrate includes a switching element disposed on a base substrate, wherein the switching element comprises a gate electrode, an active pattern, a source electrode, and a drain electrode. The display substrate also includes a first electrode disposed on a same layer as the gate electrode, wherein the first electrode includes a wire grid pattern; and a second electrode overlapping the first electrode.

This application claims priority to Korean Patent Application No. 10-2013-0082714 filed on Jul. 15, 2013, the contents of which are incorporated herein by reference in their entirety.

### BACKGROUND

1. Field of Disclosure

The present disclosure relates to a display substrate including a polarizer pattern and a method of manufacturing the same.

2. Description of the Related Art

A liquid crystal display (LCD) typically includes pixel electrodes disposed on a thin film transistor substrate, a common electrode disposed on a color filter substrate, and a liquid crystal layer interposed between the substrates. When a voltage is applied to the pixel electrodes and the common electrode, an electric field is generated between the electrodes. The liquid crystal molecules in the liquid crystal layer re-align under the influence of the electric field. The re-alignment of the liquid crystal molecules modulates the amount of light transmitted through the liquid crystal layer, thus allowing an image to be displayed on the LCD.

Since the LCD is not self-luminescent, an external light source is required to illuminate and display an image on the LCD. For example, a backlight unit may be mounted to a rear surface of the LCD to irradiate light onto the LCD panel. Also, since the electrodes in the LCD require high light transmittance, the electrodes may be formed of a transparent conductive material such as indium tin oxide (ITO) or indium zinc oxide (IZO).

The light emitted from the backlight unit passes through a polarizer before going to the LCD panel. Accordingly, the LCD displays an image based on the optical anisotropy of the liquid crystal molecules and the polarizing property of the polarizer.

The polarizer may include a polymer-type polarizer. The polymer-type polarizer can be mounted onto the LCD panel using different methods. For example, the polymer-type polarizer may include chemically bonding iodine molecules in a certain direction on a polyvinylalcohol (PVA) using a wet stretching method.

Although the polarizer has excellent polarizing properties, the polarizer is currently fabricated using a process that is separate from (and incompatible with) the LCD fabrication process. As a result, the polarizer adds to the cost of the LCD panel. Furthermore, since the polarizer is attached to the LCD panel using an adhesive, the overall thickness of the LCD panel may increase due to the additional thicknesses contributed by the adhesive and the polarizer.

The polarizer may also include other types of polarizers such as wire grid polarizers. The wire grid polarizer is typically used in products such as projectors. The wire grid polarizer is fabricated by forming stripe patterns of a metal (such as aluminum (Al)) on a base substrate using a thin-film process. It is noted that the stripe patterns may have line widths and pitches that are less than the wavelengths in the visible light spectrum.

Light from the backlight unit in the LCD vibrates in both horizontal and vertical directions with respect to the advancing direction of the light. When the light falls incident onto a wire grid polarizing pattern, only incident light that is parallel to (and that falls within the space in) the wire grid polarizing pattern passes through the wire grid polarizing pattern. As mentioned above, the wire grid polarizer includes a structure having metal-based wire grid polarizer patterns.

However, similar to the polymer-type polarizer, the wire grid polarizer is fabricated using a process that is separate from (and incompatible with) the LCD fabrication process. Also, the wire grid polarizer needs to be attached to the LCD panel. In some instances, the wire grid polarizer may be even more costly than the polymer-type polarizer due to the additional number of process steps required to fabricate and attach the wire grid polarizer to the LCD panel.

### SUMMARY

The present disclosure is directed to address at least the above deficiencies relating to polarizers in conventional liquid crystal display devices.

According to some embodiments of the inventive concept, a display substrate is provided. The display substrate includes a switching element disposed on a base substrate, wherein the switching element comprises a gate electrode, an active pattern, a source electrode, and a drain electrode; a first electrode disposed on a same layer as the gate electrode, wherein the first electrode includes a wire grid pattern; and a second electrode overlapping the first electrode.

In some embodiments, the display substrate may further include a buffer pattern disposed on the gate electrode, and wherein the gate electrode may include more than two layers.

In some embodiments, the gate electrode may include a first layer including a first metal; and a second layer disposed on the first layer, wherein the second layer may include a second metal that is different from the first metal.

In some embodiments, a thickness of the first electrode may be less than a thickness of the gate electrode, and wherein the first electrode may include the first metal.

In some embodiments, the first electrode may be electrically connected to the drain electrode, and the second electrode may include a common electrode to which a common voltage is applied.

In some embodiments, the second electrode may be electrically connected to the drain electrode, and the first electrode may include a common electrode to which a common voltage is applied.

In some embodiments, the display substrate may further include a third electrode overlapping the second electrode.

In some embodiments, the display substrate may further include a buffer pattern disposed on the gate electrode, and wherein the gate electrode may include more than two layers.

In some embodiments, the gate electrode may include a first layer including a first metal; and a second layer disposed on the first layer, wherein the second layer may include a second metal that is different from the first metal.

In some embodiments, a thickness of the first electrode may be less than a thickness of the gate electrode, and wherein the first electrode may include the first metal.

In some embodiments, the second electrode may be electrically connected to the drain electrode, and the third electrode may include a common electrode to which a common voltage is applied.

According to some other embodiments of the inventive concept, a method of manufacturing a display substrate is provided. The method includes forming a gate metal layer on a base substrate; forming an insulation layer on the gate metal layer; forming a gate electrode, a buffer pattern, and a first electrode layer by etching the gate metal layer and the insulation layer, wherein the buffer pattern is disposed on the gate electrode; forming a first electrode by etching the first electrode layer, wherein the first electrode includes a wire grid pattern; and forming a second electrode overlapping the first electrode.

In some embodiments, forming the first electrode may further include forming a block copolymer layer on the gate electrode and the first electrode layer; heating the block copolymer layer so as to initiate self-assembly of the block copolymer layer; forming a block copolymer pattern by etching the self-assembled block copolymer layer; etching the first electrode layer using the block copolymer pattern as a mask, so as to form the wire grid pattern; and removing the block copolymer pattern from the base substrate.

In some embodiments, the gate electrode may include more than two layers.

In some embodiments, forming the gate electrode may further include forming a first layer including a first metal; and forming a second layer on the first layer, wherein the second layer includes a second metal that is different from the first metal.

In some embodiments, a thickness of the first electrode may be less than a thickness of the gate electrode, and wherein the first electrode may include the first metal.

In some embodiments, the first electrode may be electrically connected to the drain electrode, and the second electrode may include a common electrode to which a common voltage is applied.

In some embodiments, the second electrode may be electrically connected to the drain electrode, and the first electrode may include a common electrode to which a common voltage is applied.

In some embodiments, the method of manufacturing the display substrate may further include forming a third electrode overlapping the second electrode.

In some embodiments, the second electrode may be electrically connected to the drain electrode, and the third electrode may include a common electrode to which a common voltage is applied.

### BRIEF DESCRIPTION OF THE DRAWINGS

FIG. 1 is a plan view illustrating a display substrate according to an exemplary embodiment of the inventive concept.

FIG. 2 is a cross-sectional view taken along line I-I′ in FIG. 1.

FIGS. 3A to 3Q are cross-sectional views illustrating a method of manufacturing the display substrate of FIGS. 1 and 2.

FIG. 4 is a plan view illustrating a display substrate according to another exemplary embodiment of the inventive concept.

FIG. 5 is a cross-sectional view taken along line II-II′ in FIG. 4.

FIGS. 6A to 6E are cross-sectional views illustrating a method of manufacturing the display substrate of FIGS. 4 and 5.

FIG. 7 is a plan view illustrating a display substrate according to a further exemplary embodiment of the inventive concept.

FIG. 8 is a cross-sectional view taken along line III-III′ in FIG. 7.

FIGS. 9A to 9G are cross-sectional views illustrating a method of manufacturing the display substrate of FIGS. 7 and 8.

### DETAILED DESCRIPTION

The inventive concept will be described herein with reference to the accompanying drawings.

When various elements (such as a layer, a film, a region, a plate, or other elements) are described as being disposed “on” another element, the elements may be disposed directly on the other element, or disposed on the other element with one or more intervening elements being present.

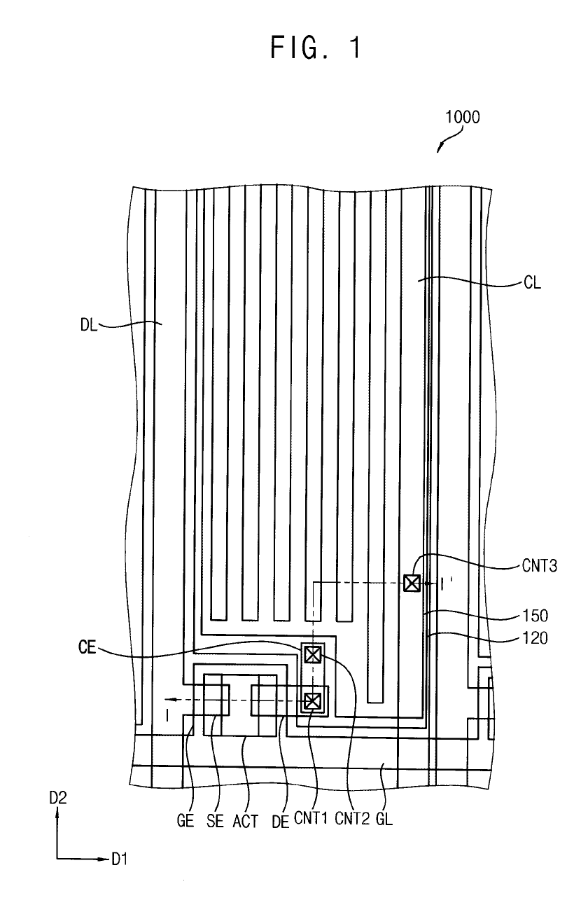

FIG. 1 is a plan view illustrating a display substrate according to an exemplary embodiment of the inventive concept.

Referring to FIG. 1, a display substrate 1000 may include a gate line GL, a data line DL, a common line CL, a pixel electrode 120, a common electrode 150, a connecting electrode CE, a first contact hole CNT1, a second contact hole CNT2, a third contact hole CNT3, and a switching element. The switching element may include a gate electrode GE, a source electrode SE, a drain electrode DE, and an active pattern ACT.

The gate line GL extends along a first direction D1. The data line DL extends along a second direction D2 substantially perpendicular to the first direction D1, and crosses the gate line GL.

The gate line GL and the data line DL define a pixel area. Although FIG. 1 depicts only one pixel area, it will be understood that the display substrate according to the inventive concept may include more than one pixel unit formed in respective pixel areas. The pixel areas may be arranged as a regular matrix structure comprising a plurality of rows and columns. The pixel areas may have a same basic and/or repeated structure.

As shown in FIG. 1, the pixel area has a rectangular shape. Nevertheless, it should be noted that the shapes and sizes of the pixel areas can be modified in different ways. For example, in some embodiments, the pixel areas may be formed having a V shape or a Z shape. Also, the color of a color filter portion or a size/shape of a pixel electrode in the pixel areas may vary between different embodiments. In some further embodiments, the pixel areas may include field-altering slits or other fine features.

As previously mentioned, the switching element includes the gate electrode GE, the source electrode SE, the drain electrode DE, and the active pattern ACT. The gate electrode GE protrudes from the gate line GL in the second direction D2, and overlaps with the active pattern ACT.

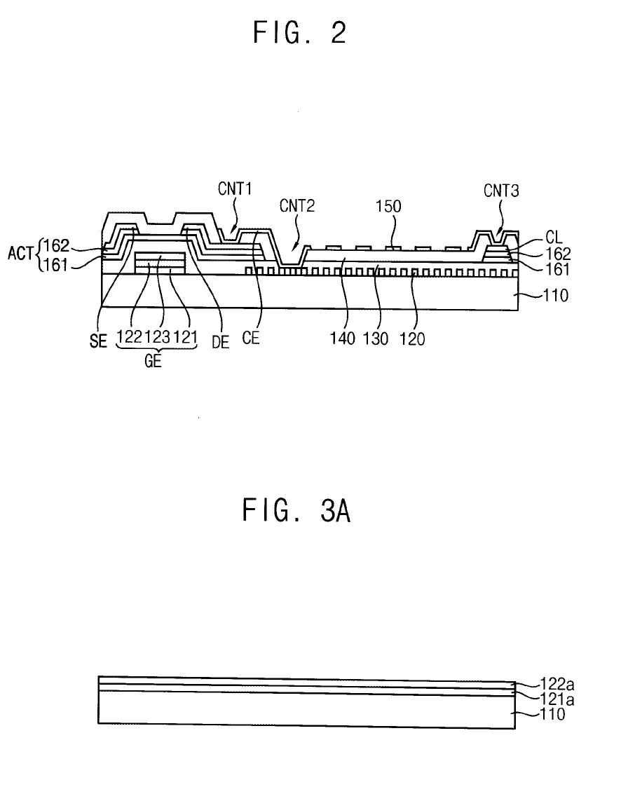

In some embodiments, the gate electrode GE may be formed as a single layer structure including copper (Cu), silver (Ag), chrome (Cr), molybdenum (Mo), aluminum (Al), titanium (Ti), or manganese (Mn). In some other embodiments, the gate electrode GE may be formed as a multi-layer structure having a plurality of layers including different materials. For example, as shown in FIG. 2, the gate electrode GE may include a lower layer 121, an upper layer 122 disposed on the lower layer 121, and a buffer pattern 123 disposed on the upper layer 122. The lower layer 121 may include titanium and the upper layer 122 may include copper.

The pixel electrode 120 is disposed in the pixel area. The pixel electrode 120 is electrically connected to the drain electrode DE through the connecting electrode CE.

The common electrode 150 may overlap with the pixel electrode 120. The common electrode 150 may be formed as a slit pattern extending along the vertical direction (i.e. second direction D2) of the pixel area. The size and/or shape of the slit pattern may be modified in different ways. For example, the slit pattern may be formed having a V shape or a Z shape. Also, the slit pattern may include field-altering slits or other fine features.

The common electrode 150 may include a transparent conductive material such as indium tin oxide (ITO) or indium zinc oxide (IZO). In addition, the common electrode 150 may include titanium (Ti) and/or molybdenum titanium (MoTi). The common electrode 150 may be electrically connected to the common line CL. A common voltage may be applied to the common electrode 150 from the common line CL. The common electrode 150 may be electrically connected to the common line CL through the third contact hole CNT3.

FIG. 2 is a cross-sectional view taken along line I-I′ in FIG. 1.

Referring to FIG. 2, the display substrate 1000 includes the above elements described in FIG. 1. The display substrate 1000 also includes a base substrate 110, a first insulation layer 130, and a second insulation layer 140.

Examples of the base substrate 110 include a glass substrate, a quartz substrate, a silicon substrate, or a plastic substrate.

The gate electrode GE is disposed on the base substrate 110. In some embodiments, the gate electrode GE may be formed as a single layer structure including copper (Cu), silver (Ag), chrome (Cr), molybdenum (Mo), aluminum (Al), titanium (Ti), or manganese (Mn). In some other embodiments, the gate electrode GE may be formed as a multi-layer structure having a plurality of layers including different materials. For example, the gate electrode GE may include a lower layer 121 and an upper layer 122 disposed on the lower layer 121. The lower layer 121 may include titanium and the upper layer 122 may include copper.

The gate electrode GE may further include a buffer pattern 123 disposed on the upper layer 122. The buffer pattern 123 may include an inorganic insulation material. For example, the buffer pattern 123 may include silicon oxide (SiOx) or silicon nitride (SiNx).

The buffer pattern 123 is disposed on the gate electrode GE. As described later in the specification, a polarizer pattern may be formed using a plasma dry etching process. However, the gate electrode GE may be damaged if the gate electrode GE is exposed to the plasma dry etching process. Accordingly, the buffer pattern 123 serves to protect the gate electrode GE from damage during the plasma dry etching process.

The pixel electrode 120 is disposed in a pixel region. The pixel electrode 120 may be formed on the same layer as the gate electrode GE. The pixel electrode 120 may be electrically connected to the drain electrode DE through the connecting electrode CE. The pixel electrode 120 may be formed as a wire grid polarizer including a polarizer pattern. The wire grid polarizer may include a metal such as aluminum (Al), copper (Cu), titanium (Ti), or molybdenum (Mo). The wire grid polarizer may be formed of the same material as the lower layer 121 of the gate electrode GE. The lower layer 121 of the gate electrode GE and the wire grid polarizer may include titanium (Ti). Since the pixel electrode 120 includes the wire grid polarizer, a separate wire grid polarizer need not be fabricated and attached on the display substrate 1000. Accordingly, the cost of the exemplary display substrate can be reduced by incorporating the wire grid polarizer into the pixel electrode 120.

In some embodiments, the pixel electrode 120 may be formed of the same material as the gate electrode GE, which reduces manufacturing cost.

As mentioned above, a separate polarizer is not required since the pixel electrode 120 includes the wire grid polarizer. Accordingly, a thickness of the display substrate and the number of process steps may be reduced using the above-described embodiment.

The first insulation layer 130 may cover the base substrate 110, the gate electrode GE, and the common electrode 120. The first insulation layer 130 may include an inorganic insulation material. For example, the first insulation layer 130 may include silicon oxide (SiOx) or silicon nitride (SiNx). In some embodiments, the first insulation layer 130 may include silicon oxide (SiOx) having a thickness of about 500 Å. In some embodiments, the first insulation layer 130 may be formed as a multi-layer structure having a plurality of layers including different materials.

The active pattern ACT may be disposed on the first insulation layer 130. Specifically, the active pattern ACT may be disposed on the first insulation layer 130 in a region where the gate electrode GE is disposed. The active pattern ACT may overlap with the gate electrode GE, and partially overlap with the source electrode SE and the drain electrode DE. The active pattern ACT may be interposed between the gate electrode GE and the source electrode SE, and between the gate electrode GE and the drain electrode DE.

The active pattern ACT may include a semiconductor layer 161 and an ohmic contact layer 162 formed on the semiconductor layer 161. The semiconductor layer 161 may include a silicon semiconductor material. For example, the semiconductor layer 161 may include amorphous silicon (a-Si:H). The ohmic contact layer 162 may be interposed between the gate electrode GE and the source electrode SE, and between the gate electrode GE and the drain electrode DE. The ohmic contact layer 162 may include n+ amorphous silicon (n+a-Si:H).

The source electrode SE and the drain electrode DE may be disposed on the active pattern ACT. The source electrode SE and the drain electrode DE may be spaced apart from each other, with the gate electrode GE disposed between the source electrode SE and the drain electrode DE.

In some embodiments, the source electrode SE and the drain electrode DE may be formed as a single layer structure including copper (Cu), silver (Ag), chrome (Cr), molybdenum (Mo), aluminum (Al), titanium (Ti), or manganese (Mn). In some other embodiments, the gate line GL may be formed as a multi-layer structure having a plurality of layers including different materials. For example, the source electrode SE and the drain electrode DE may include a copper layer and a titanium layer disposed on and/or under the copper layer.

The second insulation layer 140 may cover the source electrode SE, the drain electrode DE, and the common line CL. The first contact hole CNT1, second contact hole CNT2, and third contact hole CNT3 may be formed in the second insulation layer 140. The first contact hole CNT1 may expose a portion of the drain electrode DE. The second contact hole CNT2 may expose a portion of the pixel electrode 120. The third contact hole CNT3 may expose a portion of the common line CL. The second insulation layer 140 may include silicon oxide (SiOx) or silicon nitride (SiNx).

The connecting electrode CE and the common electrode 150 may be disposed on the second insulation layer 140.

The connecting electrode CE connects the drain electrode DE and the pixel electrode 120 through the first contact hole CNT1 and the second contact hole CNT2.

The common electrode 150 may overlap with the pixel electrode 120. The common electrode 150 may be formed as a slit pattern extending along the vertical direction (i.e. second direction D2) of the pixel area. The size and/or shape of the slit pattern may be modified in different ways. For example, the slit pattern may be formed having a V shape or a Z shape. The slit pattern may also include field-altering slits or other fine features.

The common electrode 150 may include a transparent conductive material such as indium tin oxide (ITO) or indium zinc oxide (IZO). In addition, the common electrode 150 may include titanium (Ti) and/or molybdenum titanium (MoTi). The common electrode 150 may be electrically connected to the common line CL. A common voltage may be applied to the common electrode 150 from the common line CL. The common electrode 150 may be electrically connected to the common line CL through the third contact hole CNT3.

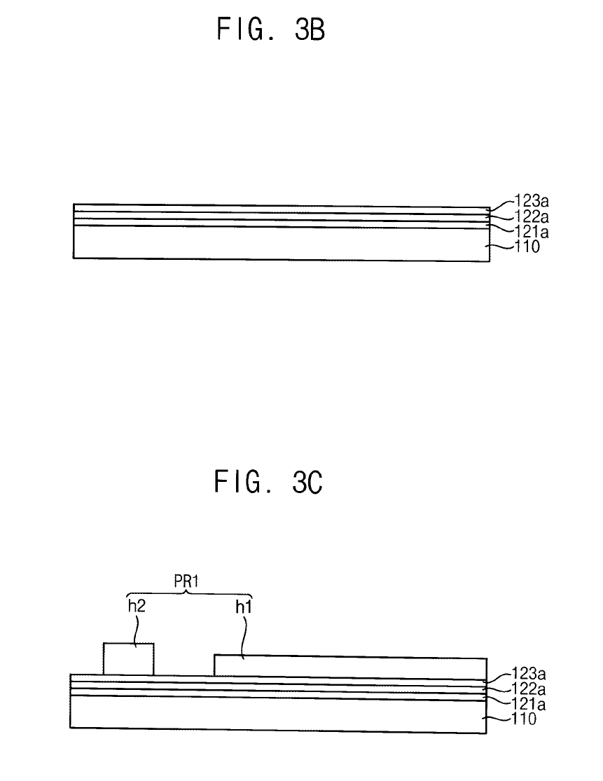

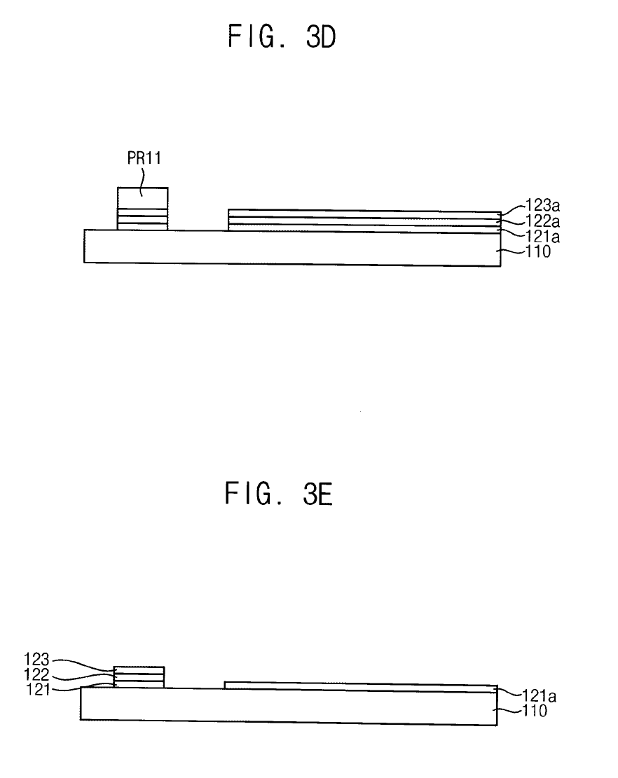

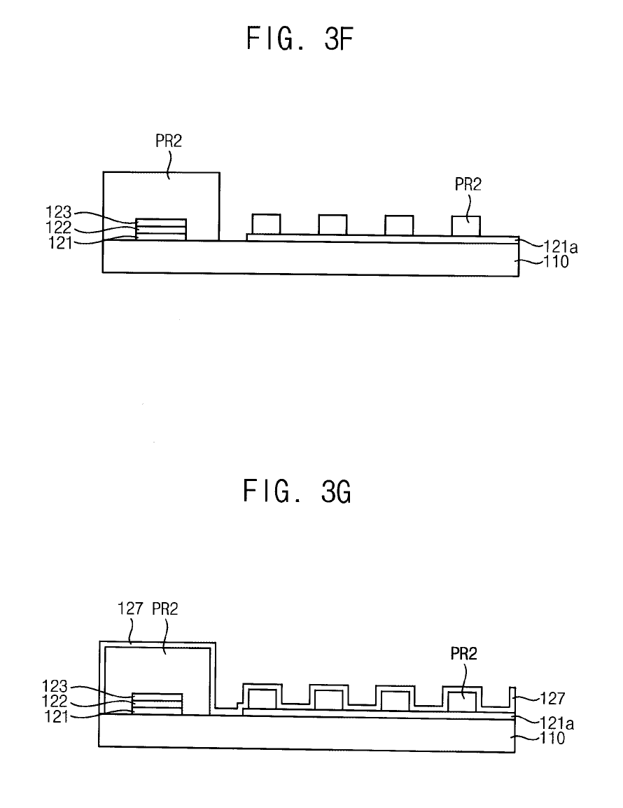

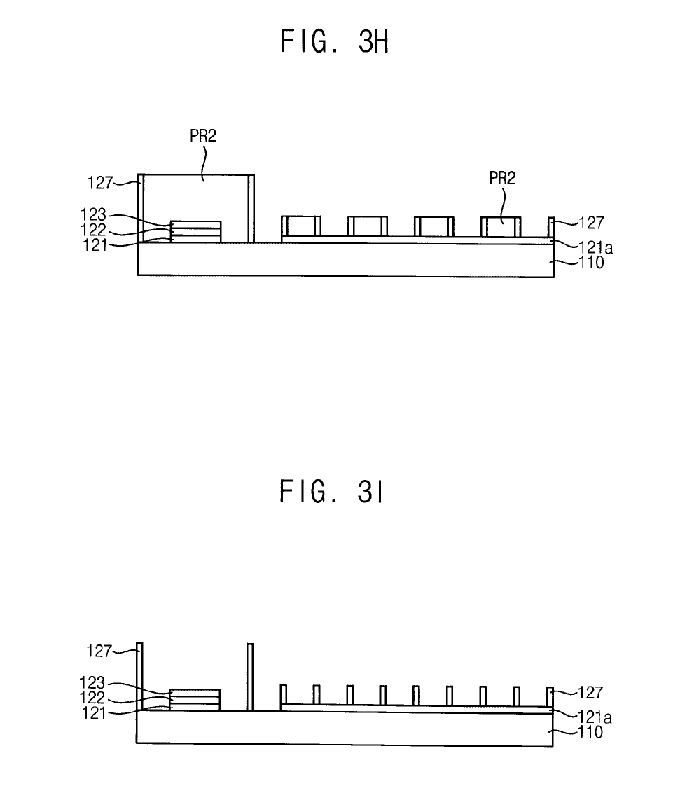

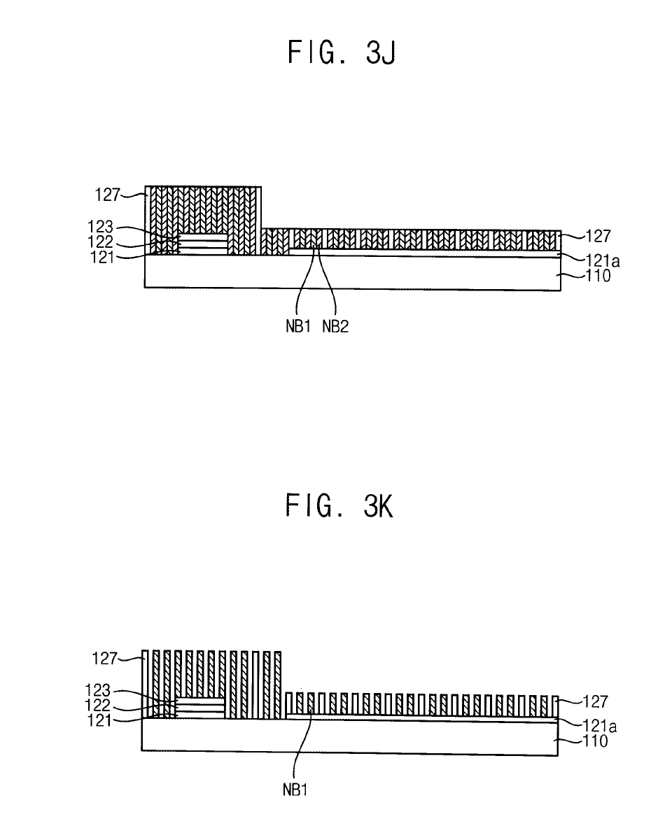

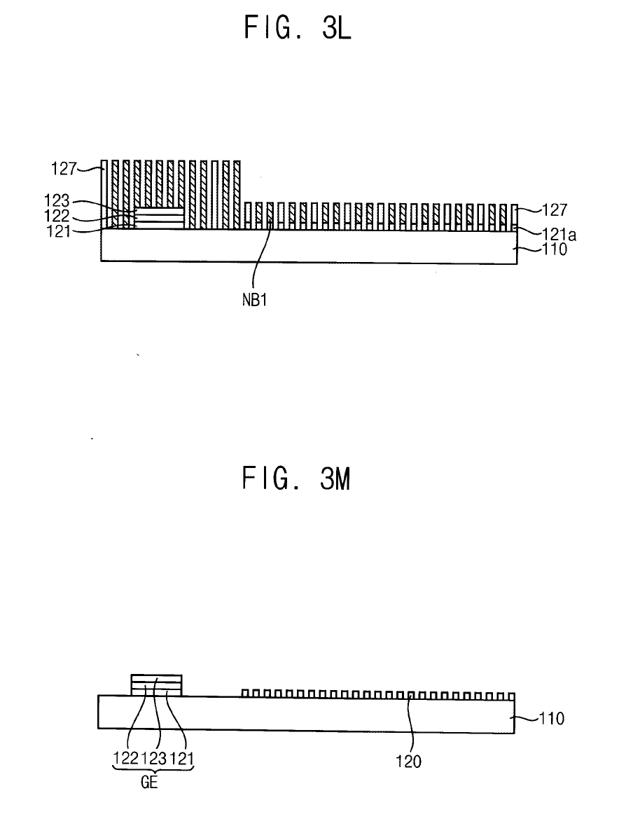

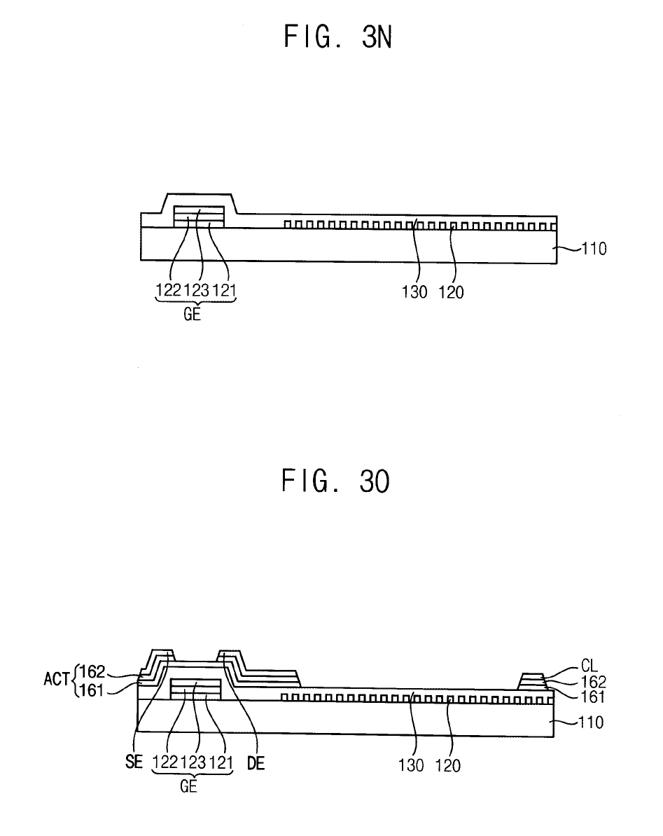

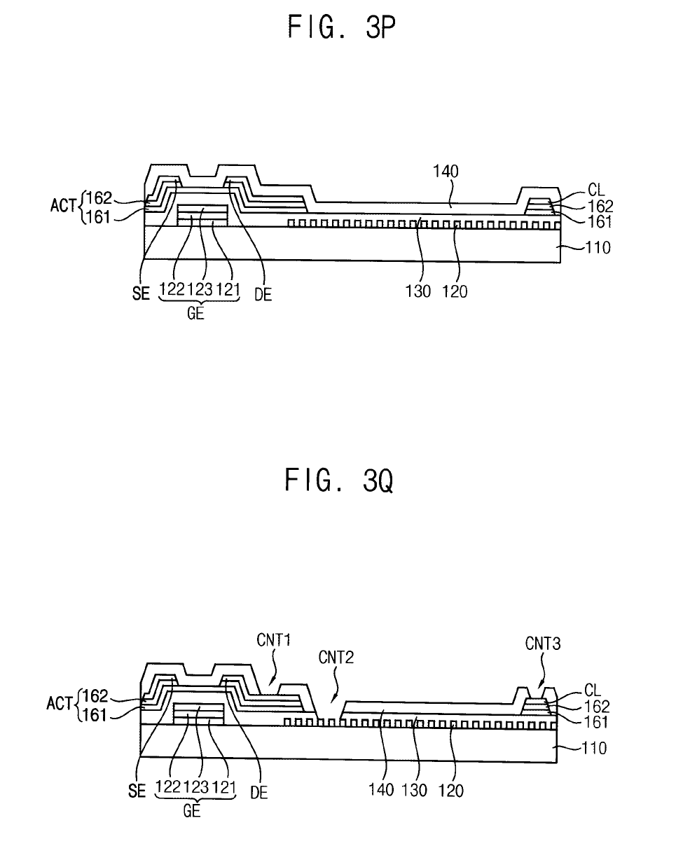

FIGS. 3A to 3Q are cross-sectional views illustrating a method of manufacturing the display substrate of FIGS. 1 and 2.

Referring to FIG. 3A, a gate metal layer is first formed on the base substrate 110. Examples of the base substrate 110 include a glass substrate, a quartz substrate, a silicon substrate, or a plastic substrate. The gate metal layer may be formed through a sputtering process. In some embodiments, the gate metal layer may be formed as a single layer structure including copper (Cu), silver (Ag), chrome (Cr), molybdenum (Mo), aluminum (Al), titanium (Ti), or manganese (Mn). In some other embodiments, the gate metal layer may be formed as a multi-layer structure having a plurality of layers including different materials. For example, the gate metal layer may include a lower layer 121a and an upper layer 122a disposed on the lower layer 121a. The lower layer 121a may include titanium and the upper layer 122a may include copper.

Referring to FIG. 3B, an insulation layer 123a is formed on the gate metal layer. The insulation layer 123a may include silicon oxide (SiOx) or silicon nitride (SiNx). As described below with reference to FIGS. 3C and 3D, the insulation layer 123a is patterned such that a portion of the insulation layer 123a remains on the gate electrode GE. The remaining portion of the insulation layer 123a serves to protect the gate electrode GE from damage during a subsequent plasma dry etching process.

Referring to FIG. 3C, a first photoresist pattern PR1 (corresponding to the locations of the gate electrode GE and the pixel electrode 120) is formed on the insulation layer 123a.

The first photoresist pattern PR1 may be formed using photolithography, soft lithography, nano-imprinting, scanning probe lithography, or other lithographic methods. The first photoresist pattern PR1 may include a first part h1 and a second part h2. The first part h1 corresponds to the pixel electrode 120 and may be formed having a first height. The second thickness part h2 corresponds to the gate electrode GE and may be formed having a second height. As shown in FIG. 3C, the second height may be greater than the first height. Next, the exposed portions of the gate metal layer (lower layer 121a and upper layer 122a) and the insulation layer 123a are etched using the first photoresist pattern PR1 as a mask. Subsequently, a remaining photoresist pattern PR11 is formed by an etch back of the first photoresist pattern PR1, as illustrated in FIG. 3D. The etch back removes the first photoresist pattern PR1 in an up-down direction and a left-right direction. As shown in FIG. 3D, the first part h1 of the first photoresist pattern PR1 is completely removed by the etch back, thereby exposing the underlying insulation layer 123a. The second part h2 of the first photoresist pattern PR1 is partially removed to form the remaining photoresist pattern PR11.

Referring to FIG. 3E, the insulation layer 123a and the gate metal layer are etched using the remaining photoresist pattern PR11 as a mask, so as to form a metal pattern for forming the gate electrode GE and the pixel electrode 120. The gate electrode GE includes a lower layer 121, an upper layer 122 disposed on the lower layer 121, and a buffer pattern 123 disposed on the upper layer 122. The lower layer 121 may include titanium and the upper layer 122 may include copper.

As shown in FIG. 3E, the metal pattern 121a is disposed on the same layer as lower layer 121. The metal pattern 121a is for forming the pixel electrode 120 and may include titanium.

Referring to FIG. 3F, a second photoresist pattern PR2 is formed in the regions of the base substrate 110 where the gate electrode GE and the metal pattern 121a are disposed. The second photoresist pattern PR2 may be formed using photolithography, soft lithography, nano-imprinting, or scanning probe lithography. The second photoresist pattern PR2 may be formed as a plurality of blocks on the base substrate 110.

Referring to FIG. 3G, a guide layer 127 is formed over the structure of FIG. 3F. The guide layer 127 may be formed covering the second photoresist pattern PR2. The guide layer 127 may include silicon oxide (SiOx) or silicon nitride (SiNx).

Referring to FIG. 3H, a portion of the guide layer 127 is removed by etching the guide layer 127. The remaining guide layer 127 is formed as a partition wall extending in a vertical direction from a cross-sectional view. As shown in FIG. 3H, the second photoresist pattern PR2 is disposed between the partition walls.

Referring to FIG. 3I, the second photoresist pattern PR2 is removed, thereby exposing the gate electrode GE and the metal pattern 121a. Although not illustrated in the figures, a neutral layer may be formed on the base substrate 110.

The neutral layer is neither hydrophobic nor hydrophilic. The neutral layer may include a self-assembled monolayer (SAM), a polymer brush, a cross-linked random copolymer mat, or an organic monolayer including a cross-linked random copolymer mat.

Materials that may be used for the self-assembled monolayer include phenethyltrichlorosilane (PETCS), phenyltrichlorosilane (PTCS), benzyltrichlorosilane (BZTCS), tolyltrichlorosilane (TTCS), 2-[(trimethoxysilyl)ethl]-2-pyridine (PYRTMS), 4-biphenylyltrimethowysilane (BPTMS), octadecyltrichlorosilane (OTS), 1-naphthyltrimehtoxysilane (NAPTMS), 1-[(trimethoxysilyl)methyl]naphthalene (MNATMS), (9-methylanthracenyl)trimethoxysilane (MANTMS), or other similar materials.

Materials that may be used for the polymer brush include polystyrene-random-poly (methylmethacrylate) (PS-random-PMMA) or other similar materials.

Materials that may be used for the cross-linked random copolymer mat include benzocyclobutene-functionalized polystyrene-r-poly (methacrylate) copolymer P(s-r-BCB-r-MMA) or other similar materials.

In some preferred embodiments, the neutral layer may include PS-random-PMMA.

The surface of the base substrate 110 may be pre-treated using an acid solution before forming the neutral layer on the surface of the base substrate 110. The acid pre-treatment increases the affinity between the base substrate 110 and the neutral layer, which improves the bonding of the neutral layer to the base substrate 110. The acid solution may include, for example, hydrofluoric acid.

Referring to FIG. 3J, a block copolymer is formed on the base substrate 110. The block copolymer be formed having a lamella shape. The block copolymer may include PS-b-PMMA.

Next, the base substrate 110 having the block copolymer is heated to form a lamella structure including a first block NB1 and a second block NB2. The lamella structure may be formed through self-assembly of the block copolymer, which includes growth of a lamella domain of one of the first and second blocks in an initial position, and growth of another lamella domain of one of the first and second blocks in a different position, as described below.

Prior to the heat treatment, the first block NB 1 and the second block NB2 are distributed in a disorderly manner. During the heat treatment, the molecules in the block copolymer move around to form a specific pattern. For example, the first blocks NB 1 form a first specific pattern, and the second blocks NB2 form a second specific pattern. The first and second specific patterns (of the blocks of the block copolymer) constitute the lamella structure.

The block copolymer may include PS-b-PMMA (poly(styrene-b-methylmethacrylate)), PS-b-PB (poly(styrene-b-butadiene)), PS-b-PI (poly(styrene-b-isoprene)), PS-b-PE (poly(styrene-b-ethylene)), PS-b-PEO (poly(styrene-b-ethyleneoxide)), PS-b-PFS (poly(styrene-b-ferrocenyldimethylsilane)), PS-b-P2VP (poly(styrene-b-(2-vinylpyridine))), or PS-b-PDMS (poly(styrene-b-dimethylsiloxane)). The block copolymer may have a molecular weight ranging from about 10,000 to about 300,000.

For example, in some embodiments, the block copolymer may include a symmetrical diblock copolymer (such as PS-b-PMMA (poly(styrene-b-methylmethacrylate)) having a molecular weight of 52,000 kg/mol with a lamellar spacing of 48 nm.

As mentioned above, the block copolymer is heat treated for self-assembly to occur. The heat treatment includes heating the block copolymer above its glass transition temperature (so that the block copolymer is more fluid) and below its thermal decomposition temperature. For example, although PS-b-PMMA can self-assemble at a temperature of about 100° C., the PS-b-PMMA may require a long time to self-assemble at that temperature. However, if the PS-b-PMMA undergoes heat treatment at a temperature of about 250° C. in a high vacuum atmosphere, the molecules in the PS-b-PMMA will flow more quickly and smoothly compared to the flow at about 100° C. Accordingly, the self-assembly of the PS-b-PMMA can be completed within a relatively shorter time at the higher temperature (of about 250° C.), with the self-assembled PS-b-PMMA having a more uniform lamella structure.

Next, a pattern is formed by removing one of the first block NB1 and the second block NB2. For example, referring to FIG. 3K, the second block NB2 is removed, so as to expose a portion of the metal pattern 121a. The second block NB2 may be removed using dry etching or wet etching. When the block copolymer includes PS-b-PMMA, the block copolymer may be dry etched using an acetic acid solution after the block copolymer undergoes UV-ozone treatment (UVO). In some embodiments, the PS-b-PMMA may be selectively removed using a dry etching process such as O2 plasma etching.

Referring to FIG. 3L, the exposed portion of the metal pattern 121a is removed, thereby forming a wire grid pattern. The size of the wire grid pattern may be adjusted by controlling the thicknesses of the metal pattern 121a, and the first block NB1 and the second block NB2 of the block copolymer. The exposed portion of the metal pattern 121a may be removed using dry etching.

Referring to FIG. 3M, the guide layer 127 and the block copolymer are removed. The guide layer 127 and the block copolymer may be removed using dry etching or wet etching. Accordingly, the gate electrode GE and the pixel electrode 120 are formed on the base substrate 110, as shown in FIG. 3M.

Referring to FIG. 3N, a first insulation layer 130 may be formed on the base substrate 110 over the gate electrode GE and the pixel electrode 120. The first insulation layer 130 may include an inorganic insulation material. For example, the first insulation layer 130 may include silicon oxide (SiOx) having thickness of about 1000 Å. In some embodiments, the first insulation layer 130 preferably has a thickness ranging from about 500 Å to about 1000 Å. In some embodiments, the first insulation layer 130 may comprise a plurality of layers including different materials.

Referring to FIG. 3O, an active pattern ACT, a source electrode SE, a drain electrode DE, and a common line CL are formed on the first insulation layer 130.

The active pattern ACT may be formed on the first insulation layer 130 in a region where the gate electrode GE is disposed. The active pattern ACT may overlap with the gate electrode GE, and partially overlap with the source electrode SE and the drain electrode DE. The active pattern ACT may be interposed between the gate electrode GE and the source electrode SE. The active pattern ACT may also be interposed between the gate electrode GE and the drain electrode DE.

The active pattern ACT may include a semiconductor layer 161 and an ohmic contact layer 162 formed on the semiconductor layer 161. The semiconductor layer 161 may include a silicon semiconductor material. For example, the semiconductor layer 161 may include amorphous silicon (a-Si:H). The ohmic contact layer 162 may be interposed between the gate electrode GE and the source electrode SE, and may be interposed between the gate electrode GE and the drain electrode DE. The ohmic contact layer 162 may include n+ amorphous silicon (n+a-Si:H).

The source electrode SE and the drain electrode DE may be formed on the active pattern ACT. The source electrode SE and the drain electrode DE may be spaced apart from each other, with the gate electrode GE disposed between the source electrode SE and the drain electrode DE.

In some embodiments, the source electrode SE and the drain electrode DE may be formed as a single layer structure including copper (Cu), silver (Ag), chrome (Cr), molybdenum (Mo), aluminum (Al), titanium (Ti), or manganese (Mn). In some other embodiments, the gate line GL may be formed as a multi-layer structure having a plurality of layers including different materials. For example, the source electrode SE and the drain electrode DE may include a copper layer and a titanium layer disposed on and/or under the copper layer.

Referring to FIG. 3P, a second insulation layer 140 is formed over the structure of FIG. 3O. Specifically, the second insulation layer 140 is formed on the active pattern ACT, source electrode SE, drain electrode DE, and common line CL. The second insulation layer 140 may include an inorganic insulation material. For example, the second insulation layer 140 may include silicon oxide (SiOx) having a thickness of about 1000 Å. In some embodiments, the second insulation layer 140 preferably has a thickness ranging from about 500 Å to about 1000 Å. In some embodiments, the second insulation layer 140 may comprise a plurality of layers including different materials.

Referring to FIG. 3Q, a first contact hole CNT1, second contact hole CNT2, and third contact hole CNT3 are formed in the second insulation layer 140. The first contact hole CNT1 may be formed through the second insulation layer 140 to expose a portion of the drain electrode DE. The second contact hole CNT2 may be formed through the second insulation layer 140 to expose a portion of the pixel electrode 120. The third contact hole CNT3 may be formed through the second insulation layer 140 to expose a portion of the common line CL.

Next, a transparent conductive layer is formed on the second insulation layer 140. The transparent conductive layer is then patterned to form the common electrode 150 and the connecting electrode CE illustrated in FIG. 2. The transparent conductive layer may include a transparent conductive material such as indium tin oxide (ITO) or indium zinc oxide (IZO).

The common electrode 150 may overlap with the pixel electrode 120. The common electrode 150 may be formed as a slit pattern extending along the vertical direction of the pixel area. The size and/or shape of the slit pattern may have modified in different ways. For example, the slit pattern may be formed having a V shape or a Z shape. The slit pattern may also include field-altering slits or other fine features.

The common electrode 150 may be electrically connected to the common line CL. A common voltage may be applied to the common electrode 150 from the common line CL. The common electrode 150 may be electrically connected to the common line CL through the third contact hole CNT3.

The connecting electrode CE may electrically connect the drain electrode DE and the pixel electrode 120. The drain electrode DE may be electrically connected to the connecting electrode CE through the first contact hole CNT1. The pixel electrode 120 may be electrically connected to the connecting electrode CE through the second contact hole CNT2. Thus, the drain electrode DE and the pixel electrode 120 may be electrically connected by the connecting electrode CE through the first contact hole CNT1 and the second contact hole CNT2.

As previously mentioned, the pixel electrode 120 may be formed of the same material as the gate electrode GE, which reduces manufacturing cost.

In addition, since the pixel electrode 120 includes the wire grid polarizer, a separate polarizer is not required. Accordingly, a thickness of a display substrate and the number of process steps may be reduced using the above-described embodiment.

Furthermore, since the buffer pattern 123 is formed on the gate metal layer, the buffer pattern 123 protects the gate electrode GE from damage during the subsequent plasma dry etching process.

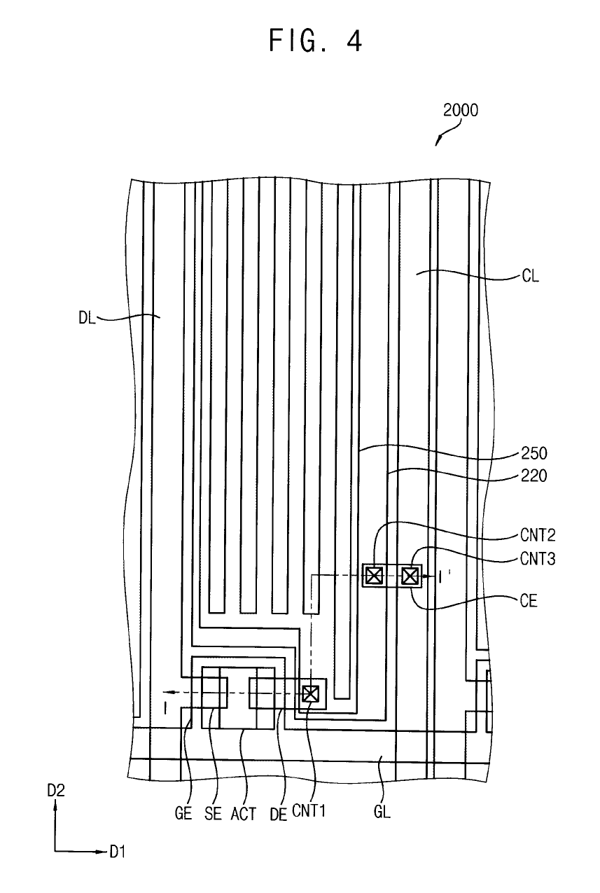

FIG. 4 is a plan view illustrating a display substrate according to another exemplary embodiment of the inventive concept.

Referring to FIG. 4, a display substrate 2000 may include a gate line GL, a data line DL, a common line CL, a connecting electrode CE, a common electrode 220, a pixel electrode 250, a first contact hole CNT1, a second contact hole CNT2, a third contact hole CNT3, and a switching element. The switching element may include a gate electrode GE, a source electrode SE, a drain electrode DE, and an active pattern ACT.

The gate line GL extends along a first direction D1. The data line DL extends along a second direction D2 substantially perpendicular to the first direction D1, and crosses the gate line GL.

The gate line GL and the data line DL define a pixel area. Although FIG. 4 depicts only one pixel area, it will be understood that the display substrate according to the inventive concept may include more than one pixel unit formed in respective pixel areas. The pixel areas may be arranged as a regular matrix structure comprising a plurality of rows and columns. The pixel areas may have a same basic and/or repeated structure.

As shown in FIG. 4, the pixel area has a rectangular shape. Nevertheless, it should be noted that the shapes and sizes of the pixel areas can be modified in different ways. For example, in some embodiments, the pixel areas may formed having a V shape or a Z shape. Also, the color of a color filter portion or a size/shape of a pixel electrode in the pixel electrode may vary between different embodiments. In some further embodiments, the pixel areas may include field-altering slits or other fine features.

As previously mentioned, the switching element includes the gate electrode GE, the source electrode SE, the drain electrode DE, and the active pattern ACT. The gate electrode GE protrudes from the gate line GL in the second direction D2, and overlaps with the active pattern ACT.

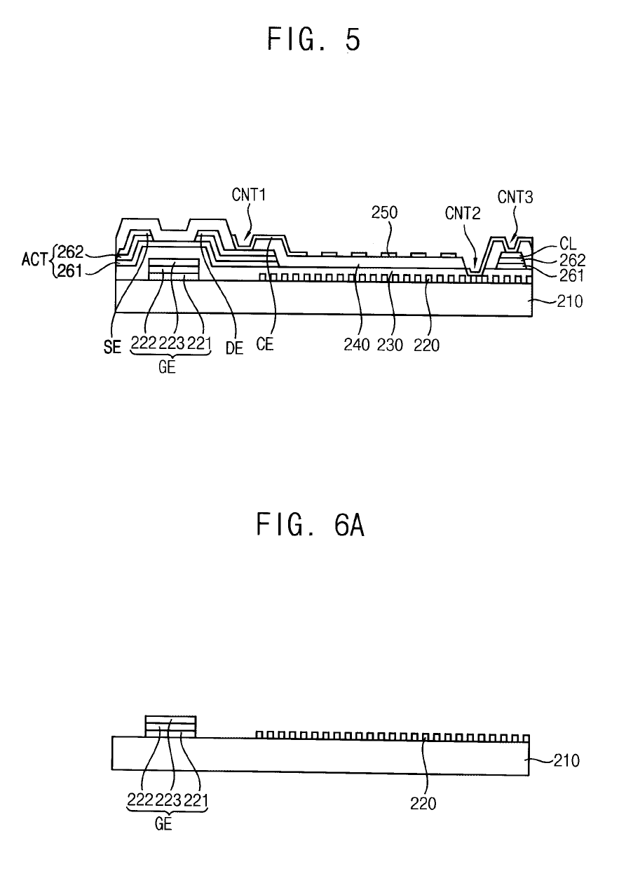

In some embodiments, the gate electrode GE may be formed as a single layer structure including copper (Cu), silver (Ag), chrome (Cr), molybdenum (Mo), aluminum (Al), titanium (Ti), or manganese (Mn). In some other embodiments, the gate electrode GE may be formed as a multi-layer structure having a plurality of layers including different materials. For example, as shown in FIG. 5, the gate electrode GE may include a lower layer 221, an upper layer 222 disposed on the lower layer 221, and a buffer pattern 223 disposed on the upper layer 222. The lower layer 221 may include titanium and the upper layer 222 may include copper.

The common electrode 220 is disposed in the pixel area beneath the pixel electrode 250. The common electrode 220 is electrically connected to the common line CL. A common voltage may be applied to the common electrode 220 from the common line CL. The common electrode 220 may be electrically connected to the common line CL through the third contact hole CNT3.

The pixel electrode 250 may overlap with the common electrode 220. The pixel electrode 250 may be formed as a slit pattern extending along the vertical direction (i.e. second direction D2) of the pixel area. The size and/or shape of the slit pattern may be modified in different ways. For example, the slit pattern may be formed having a V shape or a Z shape. Also, the slit pattern may include field-altering slits or other fine features.

The pixel electrode 250 may include a transparent conductive material such as indium tin oxide (ITO) or indium zinc oxide (IZO). In addition, the pixel electrode 250 may include titanium (Ti) and/or molybdenum titanium (MoTi).

FIG. 5 is a cross-sectional view taken along line II-II′ in FIG. 4.

Referring to FIG. 5, the display substrate 2000 includes the above elements described in FIG. 4. The display substrate 2000 also includes a base substrate 210, a first insulation layer 230, and a second insulation layer 240.

Examples of the base substrate 210 include a glass substrate, a quartz substrate, a silicon substrate, or a plastic substrate.

The gate electrode GE is disposed on the base substrate 210. In some embodiments, the gate electrode GE may be formed as a single layer structure including copper (Cu), silver (Ag), chrome (Cr), molybdenum (Mo), aluminum (Al), titanium (Ti), or manganese (Mn). In some other embodiments, the gate electrode GE may be formed as a multi-layer structure having a plurality of layers including different materials. For example, the gate electrode GE may include a lower layer 221 and an upper layer 222 disposed on the lower layer 221. The lower layer 221 may include titanium and the upper layer 222 may include copper.

The gate electrode GE may further include a buffer pattern 223 disposed on the upper layer 222. The buffer pattern 223 may include an inorganic insulation material. For example, the buffer pattern 223 may include silicon oxide (SiOx) or silicon nitride (SiNx).

The buffer pattern 223 is disposed on the gate electrode GE. As previously mentioned, a polarizer pattern may be formed using a plasma dry etching process. However, the gate electrode GE may be damaged if the gate electrode GE is exposed to the plasma dry etching process. Accordingly, the buffer pattern 223 serves to protect the gate electrode GE from damage during the plasma dry etching process.

The common electrode 220 is disposed in a pixel region. The common electrode 220 may be formed on the same layer as the gate electrode GE. As previously mentioned, the common electrode 220 is formed beneath the pixel electrode 250. A common voltage may be applied to the common electrode 220 from the common line CL. The common electrode 220 may be electrically connected to the common line CL through the third contact hole CNT3. The common electrode 220 may overlap with the pixel electrode 250.

The common electrode 220 may be formed as a wire grid polarizer including a polarizer pattern. The wire grid polarizer may include a metal such as aluminum (Al), copper (Cu), titanium (Ti), or molybdenum (Mo). The wire grid polarizer may be formed of the same material as the lower layer 221 of the gate electrode GE. The lower layer 221 of the gate electrode GE and the wire grid polarizer may include titanium (Ti). Since the common electrode 220 includes the wire grid polarizer, a separate wire grid polarizer need not be fabricated and attached on the display substrate. Accordingly, the cost of the exemplary display substrate can be reduced by incorporating the wire grid polarizer into the common electrode 220.

In some embodiments, the common electrode 220 may be formed of the same material as the gate electrode GE, which reduces manufacturing cost.

As mentioned above, a separate polarizer is not required since the pixel electrode 120 includes the wire grid polarizer. Accordingly, a thickness of the display substrate and the number of process steps may be reduced using the above-described embodiment.

The first insulation layer 230 may cover the base substrate 210, the gate electrode GE, and the common electrode 220. The first insulation layer 230 may include an inorganic insulation material. For example, the first insulation layer 230 may include silicon oxide (SiOx) or silicon nitride (SiNx). In some embodiments, the first insulation layer 230 may include silicon oxide (SiOx) having a thickness of about 500 Å. In some embodiments, the first insulation layer 230 may be formed as a multi-layer structure having a plurality of layers including different materials.

The active pattern ACT may be disposed on the first insulation layer 230. The active pattern ACT may be disposed on the first insulation layer 230 in a region where the gate electrode GE is formed. The active pattern ACT may overlap with the gate electrode GE and partially overlap with the source electrode SE and the drain electrode DE. The active pattern ACT may be interposed between the gate electrode GE and the source electrode SE. The active pattern ACT may also be interposed between the gate electrode GE and the drain electrode DE.

The active pattern ACT may include a semiconductor layer 261 and an ohmic contact layer 262 formed on the semiconductor layer 261. The semiconductor layer 261 may include a silicon semiconductor material. For example, the semiconductor layer 261 may include amorphous silicon (a-Si:H). The ohmic contact layer 262 may be interposed between the gate electrode GE and the source electrode SE, and may be interposed between the gate electrode GE and the drain electrode DE. The ohmic contact layer 262 may include form n+ amorphous silicon (n+a-Si:H).

The source electrode SE and the drain electrode DE may be disposed on the active pattern ACT. The source electrode SE and the drain electrode DE may be spaced apart from each other, with the gate electrode GE disposed between the source electrode SE and the drain electrode DE.

In some embodiments, the source electrode SE and the drain electrode DE may be formed as a single layer structure including copper (Cu), silver (Ag), chrome (Cr), molybdenum (Mo), aluminum (Al), titanium (Ti), or manganese (Mn). In some other embodiments, the gate line GL may be formed as a multi-layer structure having a plurality of layers including different materials. For example, the source electrode SE and the drain electrode DE may include a copper layer and a titanium layer disposed on and/or under the copper layer.

The second insulation layer 240 may cover the source electrode SE, the drain electrode DE, and the common line CL. The first contact hole CNT1, the second contact hole CNT2, and the third contact hole CNT3 may be formed in the second insulation layer 240. The first contact hole CNT1 may expose a portion of the drain electrode DE. The second contact hole CNT2 may expose a portion of the common electrode 220. The third contact hole CNT3 may expose a portion of the common line CL. The second insulation layer 240 may include silicon oxide (SiOx) or silicon nitride (SiNx).

The connecting electrode CE and the pixel electrode 250 may be disposed on the second insulation layer 240. The pixel electrode 250 may be electrically connected to the drain electrode DE through the first contact hole CNT1.

The pixel electrode 250 may overlap with the common electrode 220. The pixel electrode 250 may be formed as a slit pattern extending along the vertical direction (i.e. second direction D2) of the pixel area. The size and/or shape of the slit pattern may be modified in different ways. For example, the slit pattern may be formed having a V shape or a Z shape. The slit pattern may also include field-altering slits or other fine features.

The pixel electrode 250 may include a transparent conductive material such as indium tin oxide (ITO) or indium zinc oxide (IZO). In addition, the pixel electrode 250 may include titanium (Ti) and/or molybdenum titanium (MoTi).

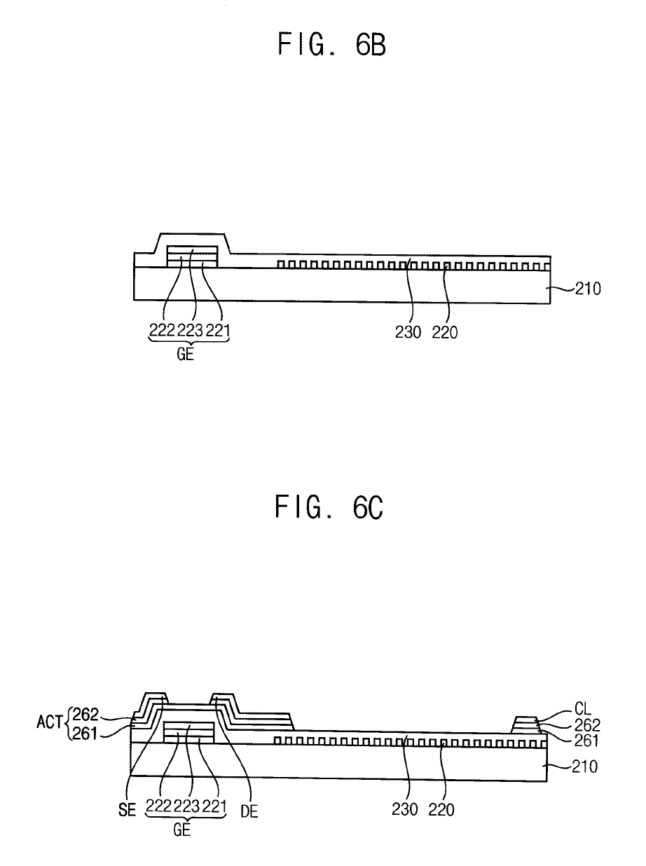

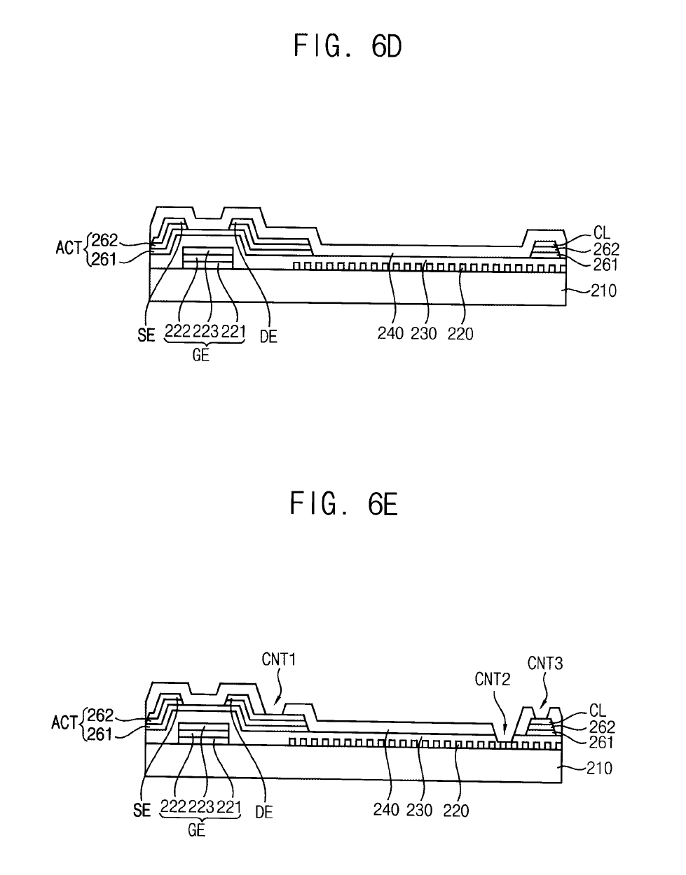

FIGS. 6A to 6E are cross-sectional views illustrating a method of manufacturing the display substrate of FIGS. 4 and 5.

Referring to FIG. 6A, the gate electrode GE and the common electrode 220 may be formed on the base substrate 210 using the same method previously described in FIGS. 3A to 3L.

The gate electrode GE includes a lower layer 221, an upper layer 222 disposed on the lower layer 221, and a buffer pattern 223 disposed on the upper layer 222. The lower layer 221 may include titanium and the upper layer 222 may include copper.

The common electrode 220 may be formed on the same layer as the lower layer 221. The common electrode 220 may include titanium. The common electrode 220 may include a wire grid pattern.

Referring to FIG. 6B, a first insulation layer 230 may be formed on the base substrate 210 over the gate electrode GE and the common electrode 220. The first insulation layer 230 may include an inorganic insulation material. For example, the first insulation layer 230 may include silicon oxide (SiOx) or silicon nitride (SiNx). In some embodiments, the first insulation layer 230 may include silicon oxide (SiOx) having a thickness of about 1000 Å. In some embodiments, the first insulation layer 230 preferably has a thickness ranging from about 500 Å to about 1000 Å. In some embodiments, the first insulation layer 230 may be formed as a multi-layer structure having a plurality of layers including different materials.

Referring to FIG. 6C, an active pattern ACT, a source electrode SE, a drain electrode DE, and a common line CL are formed on the first insulation layer 230.

The active pattern ACT may be formed on the first insulation layer 230 in a region where the gate electrode GE is disposed. The active pattern ACT may overlap with the gate electrode GE, and partially overlap with the source electrode SE and the drain electrode DE. The active pattern ACT may be interposed between the gate electrode GE and the source electrode SE, and between the gate electrode GE and the drain electrode DE.

The active pattern ACT may include a semiconductor layer 261 and an ohmic contact layer 262 formed on the semiconductor layer 261. The semiconductor layer 261 may include a silicon semiconductor material. For example, the semiconductor layer 261 may include amorphous silicon (a-Si:H). The ohmic contact layer 262 may be interposed between the gate electrode GE and the source electrode SE, and between the gate electrode GE and the drain electrode DE. The ohmic contact layer 262 may include n+ amorphous silicon (n+a-Si:H).

The source electrode SE and the drain electrode DE may be formed on the active pattern ACT. The source electrode SE and the drain electrode DE may be spaced apart from each other, with the gate electrode GE disposed between the source electrode SE and the drain electrode DE.

In some embodiments, the source electrode SE and the drain electrode DE may be formed as a single layer structure including copper (Cu), silver (Ag), chrome (Cr), molybdenum (Mo), aluminum (Al), titanium (Ti), or manganese (Mn). In some other embodiments, the gate line GL may be formed as a multi-layer structure having a plurality of layers including different materials. For example, the source electrode SE and the drain electrode DE may include a copper layer and a titanium layer disposed on and/or under the copper layer.

Referring to FIG. 6D, the second insulation layer 240 is formed over the structure of FIG. 6C. Specifically, the second insulation layer 240 is formed on the active pattern ACT, source electrode SE, drain electrode DE, and common line CL. The second insulation layer 240 may include an inorganic insulation material. For example, the second insulation layer 240 may include silicon oxide (SiOx) having a thickness of about 1000 Å. In some embodiments, the second insulation layer 240 preferably has a thickness ranging from about 500 Å to about 1000 Å. In some embodiments, the second insulation layer 240 may be formed as a multi-layer structure having a plurality of layers including different materials.

Referring to FIG. 6E, a first contact hole CNT1, a second contact hole CNT2, and a third contact hole CNT3 are formed in the second insulation layer 240. The first contact hole CNT1 may be formed through the second insulation layer 240 to expose a portion of the drain electrode DE. The second contact hole CNT2 may be formed through the second insulation layer 240 to expose a portion of the common electrode 220. The third contact hole CNT3 may be formed through the second insulation layer 240 to expose a portion of the common line CL.

Next, a transparent conductive layer is formed on the second insulation layer 240. The transparent conductive layer is then patterned to form the pixel electrode 250 illustrated in FIG. 5. The transparent conductive layer may include a transparent conductive material such as indium tin oxide (ITO) or indium zinc oxide (IZO).

The pixel electrode 250 may overlap with the common electrode 220. The pixel electrode 250 may be formed as a slit pattern extending along the vertical direction of the pixel area. The size and/or shape of the slit pattern may be modified in different ways. For example, the slit pattern may be formed having a V shape or a Z shape. The slit pattern may also include field-altering slits or other fine features. The pixel electrode 250 may be electrically connected to the drain electrode through the first contact hole CNT1.

The common electrode 220 may be electrically connected to the common line CL. A common voltage may be applied to the common electrode 220 from the common line CL. The common electrode 220 may be electrically connected to the common line CL through the third contact hole CNT3.

As previously mentioned, the common electrode 220 may be formed of the same material as the gate electrode GE, which reduces manufacturing cost.

In addition, since the common electrode 220 includes the wire grid polarizer, a separate polarizer is not required. Accordingly, a thickness of a display substrate and the number of process steps may be reduced using the above-described embodiment.

Furthermore, since the buffer pattern 223 is formed on the gate metal layer, the buffer pattern 223 protects the gate electrode GE from damage during the subsequent plasma dry etching process.

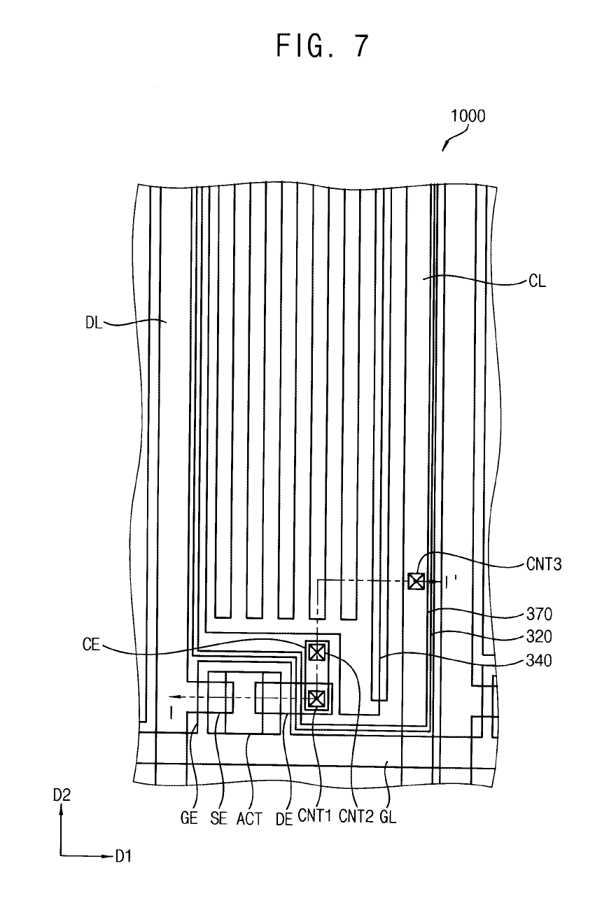

FIG. 7 is a plan view illustrating a display substrate according to a further exemplary embodiment of the inventive concept.

Referring to FIG. 7, a display substrate 3000 may include a gate line GL, a data line DL, a common line CL, a polarizer pattern 320, a pixel electrode 340, a common electrode 370, a connecting electrode CE, a first contact hole CNT1, a second contact hole CNT2, a third contact hole CNT3, and a switching element. The switching element may include a gate electrode GE, a source electrode SE, a drain electrode DE, and an active pattern ACT.

The gate line GL extends along a first direction D1. The data line DL extends along a second direction D2 substantially perpendicular to the first direction D1, and crosses the gate line GL.

The gate line GL and the data line DL define a pixel area. Although FIG. 7 depicts only one pixel area, it will be understood that the display substrate according to the inventive concept may include more than one pixel unit formed in respective pixel areas. The pixel areas may be arranged as a regular matrix structure comprising a plurality of rows and columns. The pixel areas may have a same basic and/or repeated structure.

As shown in FIG. 7, the pixel area has a rectangular shape. Nevertheless, it should be noted that the shapes and sizes of the pixel areas can be modified in different ways. For example, in some embodiments, the pixel areas may be formed having a V shape or a Z shape. Also, the color of a color filter portion or a size/shape of a pixel electrode in the pixel areas may vary between different embodiments. In some further embodiments, the pixel areas may include field-altering slits or other fine features.

As previously mentioned, the switching element includes the gate electrode GE, the source electrode SE, the drain electrode DE, and the active pattern ACT. The gate electrode GE protrudes from the gate line GL in the second direction D2, and overlaps with the active pattern ACT.

In some embodiments, the gate electrode GE may be formed as a single layer structure including copper (Cu), silver (Ag), chrome (Cr), molybdenum (Mo), aluminum (Al), titanium (Ti), or manganese (Mn). In some other embodiments, the gate electrode GE may be formed as a multi-layer structure having a plurality of layers including different materials. For example, as shown in FIG. 7, the gate electrode GE may include a lower layer 321, an upper layer 322 disposed on the lower layer 321, and a buffer pattern 323 disposed on the upper layer 322. The lower layer 321 may include titanium and the upper layer 322 may include copper.

The polarizer pattern 320 may be formed in the same layer as the gate electrode GE. For example, the polarizer pattern 320 may be formed in the same layer as the lower layer 321 of the gate electrode GE. The polarizer pattern 320 may include titanium. The polarizer pattern 320 may include a wire grid pattern.

The pixel electrode 340 is formed in the pixel area. The pixel electrode 340 is electrically connected to the drain electrode DE through the connecting electrode CE. The pixel electrode 340 may include a transparent conductive material such as indium tin oxide (ITO) or indium zinc oxide (IZO). In addition, the pixel electrode 340 may include titanium (Ti) and/or molybdenum titanium (MoTi).

The common electrode 370 may overlap with the pixel electrode 340. The common electrode 370 may be formed as a slit pattern extending along the vertical direction (i.e. second direction D2) of the pixel area. The size and/or shape of the slit pattern may be modified in different ways. For example, the slit pattern may be formed having a V shape or a Z shape. Also, the slit pattern may include field-altering slits or other fine features.

The common electrode 370 may include a transparent conductive material such as indium tin oxide (ITO) or indium zinc oxide (IZO). In addition, the common electrode 370 may include titanium (Ti) and/or molybdenum titanium (MoTi). The common electrode 370 may be electrically connected to the common line CL. A common voltage may be applied to the common electrode 370 from the common line CL. The common electrode 370 may be electrically connected to the common line CL through the third contact hole CNT3.

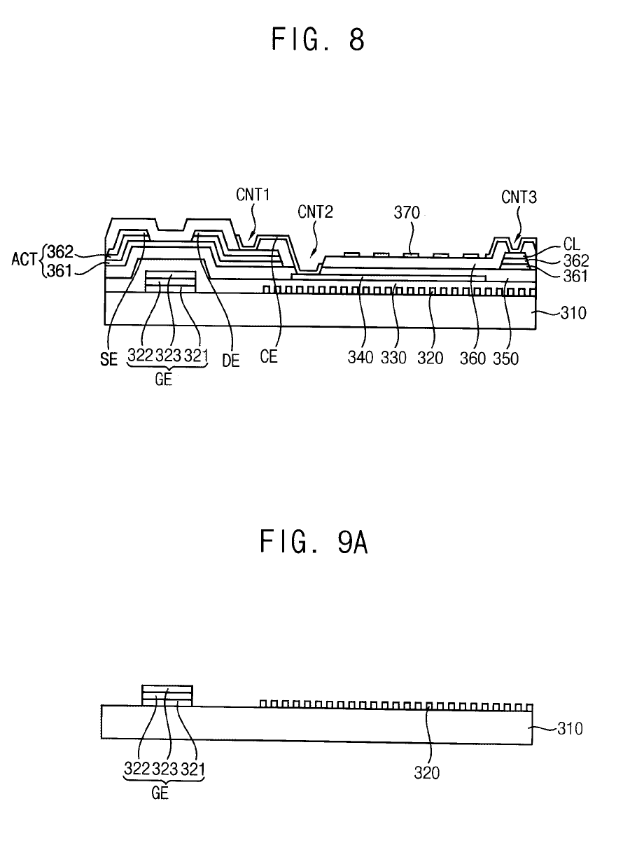

FIG. 8 is a cross-sectional view taken along line III-III′ in FIG. 7.

Referring to FIG. 8, the display substrate 3000 includes 2000 includes the above elements described in FIG. 7. The display substrate 3000 also includes a base substrate 310, a first insulation layer 330, a second insulation layer 350, and a third insulation layer 360.

Examples of the base substrate 310 include a glass substrate, a quartz substrate, a silicon substrate, or a plastic substrate.

The gate electrode GE is disposed on the base substrate 310. In some embodiments, the gate electrode GE may be formed as a single layer structure including copper (Cu), silver (Ag), chrome (Cr), molybdenum (Mo), aluminum (Al), titanium (Ti), or manganese (Mn). In some other embodiments, the gate electrode GE may be formed as a multi-layer structure having a plurality of layers including different materials. For example, the gate electrode GE may include a lower layer 321 and an upper layer 322 disposed on the lower layer 321. The lower layer 321 may include titanium and the upper layer 322 may include copper.

The gate electrode GE may further include a buffer pattern 323 disposed on the upper layer 322. The buffer pattern 323 may include an inorganic insulation material. For example, the buffer pattern 323 may include silicon oxide (SiOx) or silicon nitride (SiNx).

The buffer pattern 223 is disposed on the gate electrode GE. As previously described, a polarizer pattern may be formed using a plasma dry etching process. However, the gate electrode GE may be damaged if the gate electrode GE is exposed to the plasma dry etching process. Accordingly, the buffer pattern 223 serves to protect the gate electrode GE from damage during the plasma dry etching process.

The polarizer pattern 320 may be formed on the same layer as the gate electrode GE. The polarizer pattern 320 may be formed as a wire grid polarizer including a polarizer pattern. The wire grid polarizer may include a metal such as aluminum (Al), copper (Cu), titanium (Ti), or molybdenum (Mo). The wire grid polarizer may be formed of the same material as the lower layer 321 of the gate electrode GE. The lower layer 321 of the gate electrode GE and the wire grid polarizer may include titanium (Ti).

The first insulation layer 330 may cover the base substrate 310, the gate electrode GE, and the polarizer pattern 320. The first insulation layer 330 may include an inorganic insulation material. For example, the first insulation layer 330 may include silicon oxide (SiOx) or silicon nitride (SiNx). In some embodiments, the first insulation layer 330 may include silicon oxide (SiOx) having a thickness of about 500 Å. In some embodiments, the first insulation layer 330 may be formed as a multi-layer structure having a plurality of layers including different materials.

The pixel electrode 340 is disposed in a pixel region, and may overlap with the polarizer pattern 320. The pixel electrode 340 may be electrically connected to the drain electrode DE through the connecting electrode CE. The pixel electrode 340 may include a transparent conductive material such as indium tin oxide (ITO) or indium zinc oxide (IZO). In addition, the pixel electrode 340 may include titanium (Ti) and/or molybdenum titanium (MoTi).

The second insulation layer 350 may cover the pixel electrode 340. The second insulation layer 350 may include an inorganic insulation material. For example, the first insulation layer 130 may include silicon oxide (SiOx) or silicon nitride (SiNx). In some embodiments, the second insulation layer 350 may include silicon oxide (SiOx) having a thickness of about 500 Å. In some embodiments, the second insulation layer 350 may be formed as a multi-layer structure having a plurality of layers including different materials.

The active pattern ACT may be formed on the second insulation layer 350. The active pattern ACT may be formed on the second insulation layer 350 in a region where the gate electrode GE is disposed. The active pattern ACT may overlap with the gate electrode GE, and partially overlap with the source electrode SE and the drain electrode DE. The active pattern ACT may be interposed between the gate electrode GE and the source electrode SE, and between the gate electrode GE and the drain electrode DE.

The active pattern ACT may include a semiconductor layer 361 and an ohmic contact layer 362 formed on the semiconductor layer 361. The semiconductor layer 361 may include a silicon semiconductor material. For example, the semiconductor layer 361 may include amorphous silicon (a-Si:H). The ohmic contact layer 362 may be interposed between the gate electrode GE and the source electrode SE, and between the gate electrode GE and the drain electrode DE. The ohmic contact layer 362 may include n+ amorphous silicon (n+a-Si:H).

The source electrode SE and the drain electrode DE may be formed on the active pattern ACT. The source electrode SE and the drain electrode DE may be spaced apart from each other, with the gate electrode GE disposed between the source electrode SE and the drain electrode DE.

In some embodiments, the source electrode SE and the drain electrode DE may be formed as a single layer structure including copper (Cu), silver (Ag), chrome (Cr), molybdenum (Mo), aluminum (Al), titanium (Ti), or manganese (Mn). In some other embodiments, the gate line GL may be formed as a multi-layer structure having a plurality of layers including different materials. For example, the source electrode SE and the drain electrode DE may include a copper layer and a titanium layer disposed on and/or under the copper layer.

The third insulation layer 360 may cover the source electrode SE, the drain electrode DE, and the common line CL. The first contact hole CNT1, the second contact hole CNT2, and the third contact hole CNT3 may be formed in the third insulation layer 360. The first contact hole CNT1 may expose a portion of the drain electrode DE. The second contact hole CNT2 may expose a portion of the pixel electrode 340. The third contact hole CNT3 may expose a portion of the common line CL. The third insulation layer 360 may include silicon oxide (SiOx) or silicon nitride (SiNx).

The connecting electrode CE and the common electrode 370 may be formed on the third insulation layer 370. The connecting electrode CE connects the drain electrode DE and the pixel electrode 340 through the first contact hole CNT1 and the second contact hole CNT2. The drain electrode DE may be electrically connected to the connecting electrode CE through the first contact hole CNT1. The pixel electrode 340 may be electrically connected to the connecting electrode CE through the second contact hole CNT2. Thus, the drain electrode DE and the pixel electrode 340 may be electrically connected to each other by the connecting electrode CE through the first contact hole CNT1 and the second contact hole CNT2.

The common electrode 370 may overlap with the pixel electrode 340. The common electrode 370 may be formed as a slit pattern extending along the vertical direction (i.e. second direction D2) of the pixel area. The size and/or shape of the slit pattern may be modified in different ways. For example, the slit pattern may be formed having a V shape or a Z shape. The slit pattern may also include field-altering slits or other fine features.

The common electrode 370 may include a transparent conductive material such as indium tin oxide (ITO) or indium zinc oxide (IZO). In addition, the common electrode 370 may include titanium (Ti) and/or molybdenum titanium (MoTi). The common electrode 370 may be electrically connected to the common line CL. A common voltage may be applied to the common electrode 370 from the common line CL. The common electrode 370 may be electrically connected to the common line CL through the third contact hole CNT3.

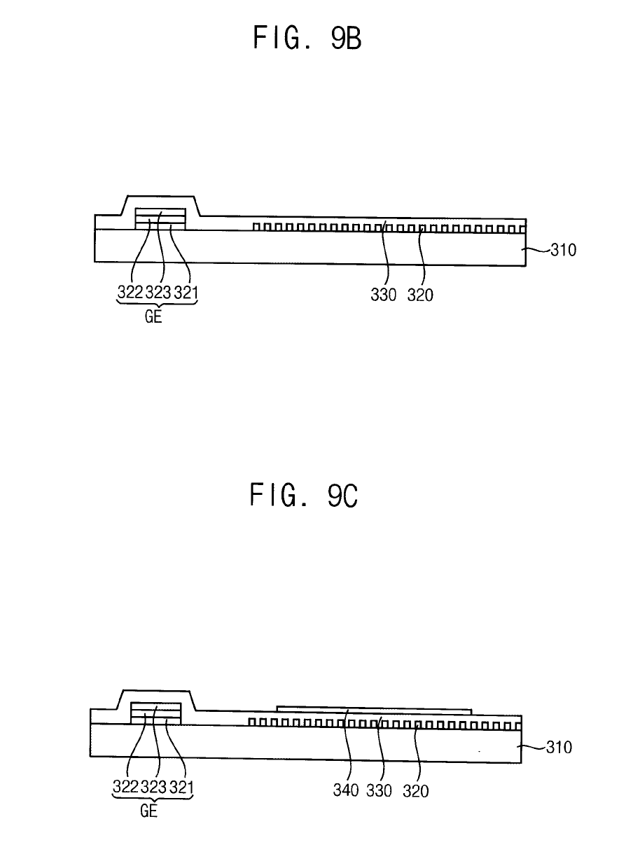

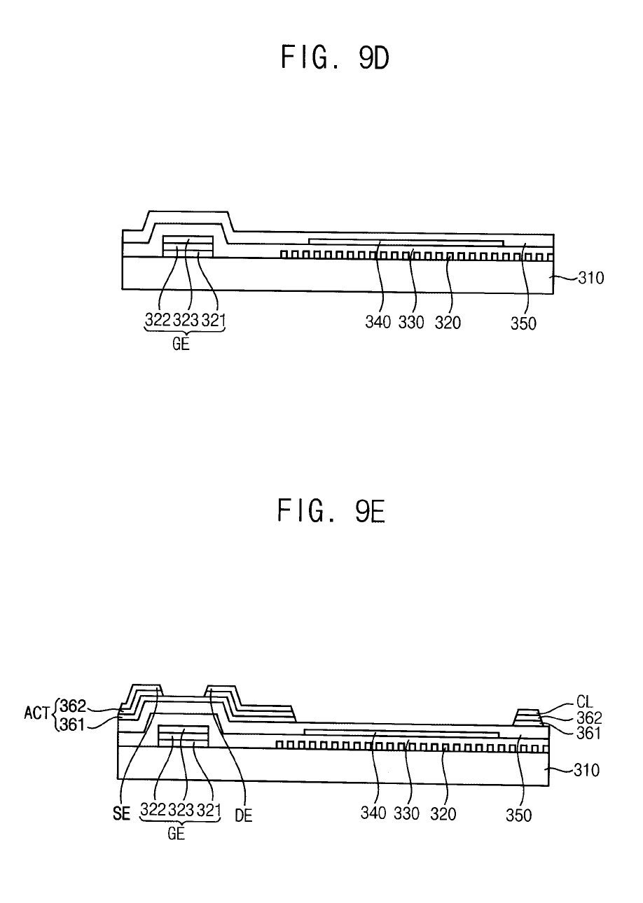

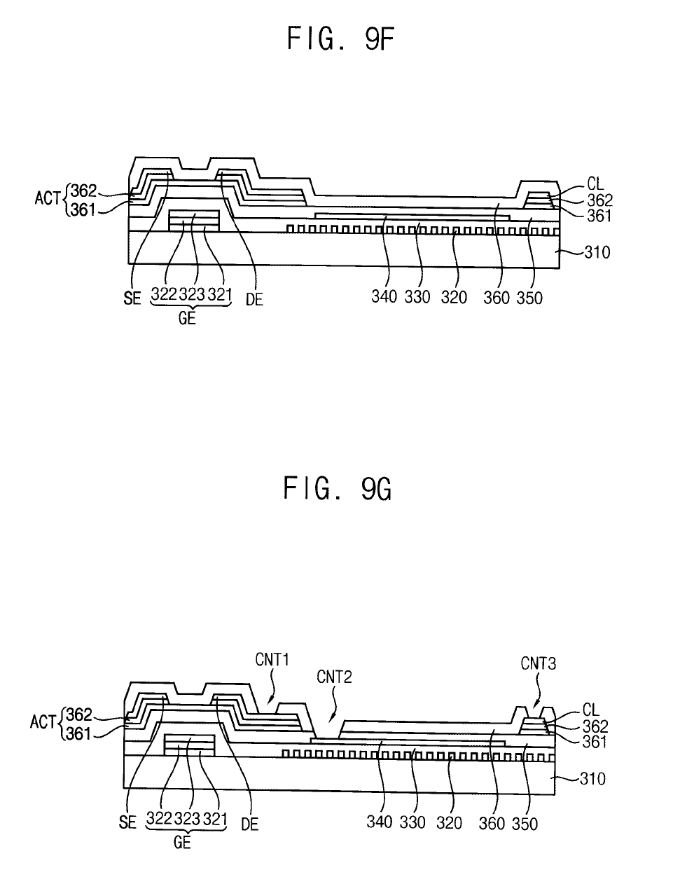

FIGS. 9A to 9G are cross-sectional views illustrating a method of manufacturing the display substrate of FIGS. 7 and 8.

Referring to FIG. 9A, the gate electrode GE and the polarizer pattern 320 may be formed on the base substrate 310 using the same method previously described in FIGS. 3A to 3L. The gate electrode GE may include a lower layer 321, an upper layer 322 disposed on the lower layer 321, and a buffer pattern 323 disposed on the upper layer 322. The lower layer 321 may include titanium and the upper layer 322 may include copper.

The polarizer pattern 320 may by formed as a wire grid polarizer including a wire grid pattern. The wire grid polarizer may include a metal such as aluminum (Al), copper (Cu), titanium (Ti), or molybdenum (Mo). The wire grid polarizer may be formed of the same material as the lower layer 321 of the gate electrode GE. The lower layer 321 of the gate electrode GE and the wire grid polarizer may include titanium (Ti).

Referring to FIG. 9B, a first insulation layer 330 may be formed on the base substrate 310 over the gate electrode GE and the polarizer pattern 320. The first insulation layer 330 may include an inorganic insulation material. For example, the first insulation layer 330 may include silicon oxide (SiOx) or silicon nitride (SiNx). In some embodiments, the first insulation layer 330 may include silicon oxide (SiOx) having a thickness of about 1000 Å. In some embodiments, the first insulation layer 330 preferably has a thickness ranging from about 500 Å to about 1000 Å. In some embodiments, the first insulation layer 330 may be formed as a multi-layer structure having a plurality of layers including different materials.

Referring to FIG. 9C, the pixel electrode 340 is formed on the region of the base substrate 310 where the first insulation layer 330 is disposed. The pixel electrode 340 may overlap with the polarizer pattern 320. The pixel electrode 340 may be electrically connected to the drain electrode DE through the connecting electrode CE. The pixel electrode 340 may include a transparent conductive material such as indium tin oxide (ITO) or indium zinc oxide (IZO). In addition, the pixel electrode 340 may include titanium (Ti) and/or molybdenum titanium (MoTi).

Referring to FIG. 9D, the second insulation layer 350 is formed over the structure of FIG. 9C. The second insulation layer 350 may include an inorganic insulation material. For example, the second insulation layer 350 may include silicon oxide (SiOx) having a thickness of about 1000 Å. In some embodiments, the second insulation layer 350 preferably has a thickness ranging from about 500 Å to 1000 Å. In some embodiments, the second insulation layer 350 may be formed as a multi-layer structure having a plurality of layers including different materials.

Referring to FIG. 9E, the active pattern ACT, the source electrode SE, the drain electrode DE, and the common electrode CE are formed on the second insulation layer 350.

The active pattern ACT may be formed on the second insulation layer 350 in a region where the gate electrode GE is disposed. The active pattern ACT may overlap with the gate electrode GE, and partially overlap with the source electrode SE and the drain electrode DE. The active pattern ACT may be interposed between the gate electrode GE and the source electrode SE, and between the gate electrode GE and the drain electrode DE.

The active pattern ACT may include a semiconductor layer 361 and an ohmic contact layer 362 formed on the semiconductor layer 361. The semiconductor layer 361 may include a silicon semiconductor material. For example, the semiconductor layer 361 may include amorphous silicon (a-Si:H). The ohmic contact layer 362 may be interposed between the gate electrode GE and the source electrode SE, and between the gate electrode GE and the drain electrode DE. The ohmic contact layer 362 may include n+ amorphous silicon (n+a-Si:H).

The source electrode SE and the drain electrode DE may be formed on the active pattern ACT. The source electrode SE and the drain electrode DE may be spaced apart from each other, with the gate electrode GE between the source electrode SE and the drain electrode DE.

In some embodiments, the source electrode SE and the drain electrode DE may be formed as a single layer structure including copper (Cu), silver (Ag), chrome (Cr), molybdenum (Mo), aluminum (Al), titanium (Ti), or manganese (Mn). In some other embodiments, the gate line GL may be formed as a multi-layer structure having a plurality of layers including different materials. For example, the source electrode SE and the drain electrode DE may include a copper layer and a titanium layer disposed on and/or under the copper layer.

Referring to FIG. 9F, the third insulation layer 360 is formed on the active pattern ACT, source electrode SE, drain electrode DE, and common line CL. The third insulation layer 360 may include an inorganic insulation material. For example, the third insulation layer 360 may include silicon oxide (SiOx) having a thickness of about 1000 Å. In some embodiments, the third insulation layer 360 preferably has a thickness ranging from about 500 Å to 1000 Å. In some embodiments, the third insulation layer 360 may include a plurality of layers including different materials.

Referring to FIG. 9G, the first contact hole CNT1, the second contact hole CNT2, and the third contact hole CNT3 are formed in the third insulation layer 360.

The first contact hole CNT1 may be formed through the third insulation layer 360 to expose a portion of the drain electrode DE. The second contact hole CNT2 may be formed through the third insulation layer 360 to expose a portion of the pixel electrode 340. The third contact hole CNT3 may be formed through the third insulation layer 360 to expose a portion of the common line CL.

Next, a transparent conductive layer is formed on the third insulation layer 360. The transparent conductive layer is then patterned to form the common electrode 370 and the connecting electrode CE illustrated in FIG. 8. The transparent conductive layer may include a transparent conductive material such as indium tin oxide (ITO) or indium zinc oxide (IZO).

The common electrode 370 may overlap with the pixel electrode 340. The common electrode 370 may be formed as a slit pattern extending along the vertical direction of the pixel area. The size and/or shape of the slit pattern may be modified in different ways. For example, the slit pattern may be formed having a V shape or a Z shape. The slit pattern may also include field-altering slits or other fine features. The common electrode 370 may be electrically connected with the common line CL. A common voltage may be applied to the common electrode 370 from the common line CL. The common electrode 370 may be electrically connected to the common line CL through the third contact hole CNT3.

The connecting electrode CE connects the drain electrode DE and the pixel electrode 340 through the first contact hole CNT1 and the second contact hole CNT2. The drain electrode DE may be electrically connected to the connecting electrode CE through the first contact hole CNT1. The pixel electrode 340 may be electrically connected to the connecting electrode CE through the second contact hole CNT2. Thus, the drain electrode DE and the pixel electrode 340 may be electrically connected by the connecting electrode CE through the first contact hole CNT1 and the second contact hole CNT2.

In some embodiments, the polarizer pattern 320 may be formed of the same material as the gate electrode GE, which reduces manufacturing cost.

In some embodiments, the common electrode 370 may be formed of the same material as the gate electrode GE, which reduces manufacturing cost.

In some embodiments, the pixel electrode 340 may be formed of the same material as the gate electrode GE, which reduces manufacturing cost.

As previously described, since the pixel electrode or the common electrode includes a wire grid polarizer, a separate polarizer is not required. Accordingly, a thickness of the display substrate and the number of process steps may be reduced using the above-described embodiments.

Furthermore, since the buffer pattern 323 is formed on the gate metal layer, the buffer pattern 323 protects the gate electrode GE from damage during the plasma dry etching process.

It should be understood that the above-described embodiments are merely exemplary, and should not be construed as limiting the inventive concept. While the inventive concept has been described with reference to exemplary embodiments, it will be understood by those of ordinary skill in the art that various modifications may be made to the described embodiments without departing from the spirit and scope of the present disclosure.

What is claimed is:

1. A display substrate comprising:
a switching element disposed on a base substrate, wherein the switching element comprises a gate electrode, an active pattern, a source electrode, and a drain electrode;
a first electrode disposed on a same layer as the gate electrode, wherein the first electrode includes a wire grid pattern; and
a second electrode overlapping the first electrode.

2. The display substrate of claim 1, further comprising a buffer pattern disposed on the gate electrode, and wherein the gate electrode comprises more than two layers.

3. The display substrate of claim 2, wherein the gate electrode comprises:
a first layer including a first metal; and
a second layer disposed on the first layer, wherein the second layer includes a second metal that is different from the first metal.

4. The display substrate of claim 3, wherein a thickness of the first electrode is less than a thickness of the gate electrode, and wherein the first electrode includes the first metal.

5. The display substrate of claim 1, wherein the first electrode is electrically connected to the drain electrode, and the second electrode includes a common electrode to which a common voltage is applied.

6. The display substrate of claim 1, wherein the second electrode is electrically connected to the drain electrode, and the first electrode includes a common electrode to which a common voltage is applied.

7. The display substrate of claim 1, further comprising a third electrode overlapping the second electrode.

8. The display substrate of claim 7, further comprising a buffer pattern disposed on the gate electrode, and wherein the gate electrode comprises more than two layers.

9. The display substrate of claim 8, wherein the gate electrode comprises:
a first layer including a first metal; and
a second layer disposed on the first layer, wherein the second layer includes a second metal that is different from the first metal.

10. The display substrate of claim 9, wherein a thickness of the first electrode is less than a thickness of the gate electrode, and wherein the first electrode includes the first metal.

11. The display substrate of claim 7, wherein the second electrode is electrically connected to the drain electrode, and the third electrode includes a common electrode to which a common voltage is applied.

12. A method of manufacturing a display substrate comprising:
forming a gate metal layer on a base substrate;
forming an insulation layer on the gate metal layer;
forming a gate electrode, a buffer pattern, and a first electrode layer by etching the gate metal layer and the insulation layer, wherein the buffer pattern is disposed on the gate electrode;
forming a first electrode by etching the first electrode layer, wherein the first electrode includes a wire grid pattern; and
forming a second electrode overlapping the first electrode.

13. The method of claim 12, wherein forming the first electrode further comprises:
forming a block copolymer layer on the gate electrode and the first electrode layer;
heating the block copolymer layer so as to initiate self-assembly of the block copolymer layer;
forming a block copolymer pattern by etching the self-assembled block copolymer layer;
etching the first electrode layer using the block copolymer pattern as a mask, so as to form the wire grid pattern; and
removing the block copolymer pattern from the base substrate.

14. The method of claim 12, wherein the gate electrode comprises more than two layers.

15. The method of claim 14, wherein forming the gate electrode further comprises:
forming a first layer including a first metal; and
forming a second layer on the first layer, wherein the second layer includes a second metal that is different from the first metal.

16. The method of claim 15, wherein a thickness of the first electrode is less than a thickness of the gate electrode, and wherein the first electrode includes the first metal.

17. The method of claim 16, wherein the first electrode is electrically connected to the drain electrode, and the second electrode includes a common electrode to which a common voltage is applied.

18. The method of claim 16, wherein the second electrode is electrically connected to the drain electrode, and the first electrode includes a common electrode to which a common voltage is applied.

19. The method of claim 12, further comprising forming a third electrode overlapping the second electrode.

20. The method of claim 19, wherein the second electrode is electrically connected to the drain electrode, and the third electrode includes a common electrode to which a common voltage is applied.
